(19) United States
(12) Patent Application Publication
(10) Pub. No.: US 2015/0243812 A1
(43) Pub. Date: Aug. 27, 2015

(54) SILVER NANOPARTICLE BASED COMPOSITE SOLAR METALLIZATION PASTE

(71) Applicant: PLANT PV, Inc., Belmont, CA (US)

(72) Inventors: Brian E. Hardin, Berkeley, CA (US); Stephen T. Connor, San Francisco, CA (US); James Randy Groves, Sunnyvale, CA (US); Craig H. Peters, Belmont, CA (US); Jose Marcial Portilla, Berkeley, CA (US)

(21) Appl. No.: 14/706,971

(22) Filed: May 8, 2015

Related U.S. Application Data
(63) Continuation-in-part of application No. 14/311,239, filed on Jun. 20, 2014.
(60) Provisional application No. 61/881,394, filed on Sep. 23, 2013.
(60) Provisional application No. 61/986,020, filed on Apr. 29, 2014.
(60) Provisional application No. 61/986,025, filed on Apr. 29, 2014.
(60) Provisional application No. 62/011,496, filed on Jun. 12, 2014.
(60) Provisional application No. 61/837,575, filed on Jun. 20, 2013.
(60) Provisional application No. 62/011,496, filed on Jun. 12, 2014.

(51) Int. Cl. H01L 31/0224; C09D 5/24

(52) U.S. Cl. CPC H01L 31/022433; C09D 5/24

(57) ABSTRACT

Metallization pastes for use with semiconductor devices are disclosed. The pastes contain silver nanoparticles, silver microparticles, and nondeformable inorganic material particles. Specific formulations have been developed that yield printed lines with low porosities and high peel strengths.

### CROSS-REFERENCE TO RELATED APPLICATIONS

This application claims priority to U.S. Provisional Patent Application 62/011,496, filed Jun. 12, 2014 and is also a Continuation in Part of U.S. patent application Ser. No. 14/311,239, filed Jun. 20, 2014, which also claims priority to U.S. Provisional Patent Application 61/837,575, filed Jun. 20, 2013, U.S. Provisional Patent Application 61/881,394, filed Sep. 23, 2013, U.S. Provisional Patent Application 61/986,020, filed Apr. 29, 2014, and U.S. Provisional Patent Application 61/986,025, filed Apr. 29, 2014. This application is also a Continuation of International Patent Application PCT/US14/71608, filed Dec. 19, 2014. All of these patent applications are incorporated by reference herein.

### STATEMENT OF GOVERNMENT SUPPORT

The invention described and claimed herein was made in part utilizing funds supplied by the National Science Foundation under SBIR Contract No. IIP-1315284. The Government has certain rights in this invention.

### TECHNICAL FIELD

Embodiments of the present disclosure relate to conductive metallization pastes and inks for use with silicon based solar cells and other semiconductor devices.

### BACKGROUND

Screen printable metallization pastes are used to make electrical contact to silicon photovoltaic (PV) cells and to connect PV cells together. The cells are connected in series by making electrical contact between the metallization layers and solder coated, Cu tabbing ribbons. Three primary paste formulations are used in silicon based PV cells: 1) rear side aluminum paste, 2) rear side silver tabbing paste, and 3) front side silver paste. FIG. 1 is a schematic drawing that shows an example of silver-based metallization paste 100. The paste 100 has silver particles 110, glass frit 120, and an organic binder 130 mixed with solvent. Examples of pure silver, rear tabbing pastes made by DuPont™ (Solamet® PV52A) and by Heraeus (SOL230H) contain 45-66% conductive particles by weight and are designed to reduce silver loading and have a resulting thickness between 3 and 10 μm after screen printing, drying, and co-firing. In some examples, the silver particles are a mixture of silver flakes that are 1 to 3 μm in diameter and silver spheres with a distribution of sizes ranging in diameter from 100 nm to 5 μm. Examples of pure silver, front metallization pastes made by DuPont™ (Solamet® (PV17x) and Heraeus (SOL9235H) contain more than 90 wt % conductive particles. Such front metallization pastes contain spherical silver particles that range in size between 300 nm and 5 μm. Such pastes are formulated to print lines that have a high aspect ratio, compact densely to improve bulk conductivity, and make ohmic contact to the emitter layer of a silicon solar cell.

In the most widely commercialized Si solar cell architecture, aluminum paste is used on >95% of the back side to form an ohmic contact to p-type Si, creating a back-surface field to improve PV performance. Rear side silver tabbing paste occupies regions not coated with aluminum paste and is used to promote strong adhesion to Si as well as solderability to solder coated Cu tabbing ribbon, as soldering directly to the aluminum paste is challenging. Front side silver paste is formulated to penetrate through the anti-reflective coating to make ohmic contact to the front, n-type silicon. During silicon PV cell processing each paste layer is screen printed successively and dried at low temperatures (e.g., about 100-250° C.). Once the three layers are printed, the entire wafer is co-fired to 650-900° C. for approximately one second in air to form ohmic contacts and promote paste adhesion to the silicon.

Silver based metallization pastes are inherently expensive because of the amount of Ag required and the commodity price of Ag, which is close to $625/kg in 2014. Silver based metallization pastes are the second largest materials cost for Si PV modules, and it is estimated that the PV industry currently uses more than 5% of all annual silver production. Continued, large increases in PV cell production will use more and more silver, which may become prohibitively expensive and unsustainable in the long-term.

Silver nanoparticles may offer the advantages of higher compaction and lower roughness, which enables the use of thinner printed films. Silver nanoparticles are known to deform and sinter at relatively low temperatures (e.g., less than 300° C.), and micron-sized silver particles are known to deform in the presence of glass frits (e.g., PbO and Bi₂O₃) at higher temperatures. One method to make silver film electrodes is to print silver particles and heat them to form a dense sintered network. The size of the silver particles, the composition of the frits, the firing temperatures, and ramp up and cool down rates are all important factors that affect the internal stress of the resulting films and their ability to adhere to a substrate (e.g., silicon) that has a different coefficient of thermal expansion.

Silver nanoparticles have been printed to form thin films (i.e., less than 1 μm) and annealed at relatively low temperatures (i.e., less than 600° C.). However, thick films made from pastes where nanoparticles form the majority of particles by weight have high internal stresses and often crack and delaminate when the films become thicker than 500 nm, which render them useless for solar cell electrodes (see J. R. Greer, “Mechanical characterization of solution-derived nanoparticle silver ink thin films,” J. App. Phys. 101, 103529 (2007)).

FIG. 2A is a schematic cross-section illustration of such a silver nanoparticle metallization layer 210 on a substrate 220 before firing. FIG. 2B is a schematic cross-section illustration of such a silver nanoparticle metallization layer 215 on a substrate 220 after firing. Although silver nanoparticle pastes can be printed as a layer 210 onto a substrate 220, the layer 210 cracks and curls up after firing, as shown in layer 215 in FIG. 2B, losing contact to the substrate 220 at the edges. Such profiles cannot be used in solar cells or any other semiconductor devices that are fired to temperatures greater than 700° C., as they have reduced contact area and are prone to even further peeling.

What is needed is a metallization paste that offers reduced silver content, easy processing, good adhesion, and lines that can last at least as long as the devices on which they are used.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1 is a schematic drawing of a silver metallization paste (prior art).

FIG. 2A is a schematic cross-section illustration of a silver nanoparticle metallization layer on a substrate before firing.

FIG. 2B is a schematic cross-section illustration of a silver nanoparticle metallization layer on a substrate after firing.

FIG. 3A is a schematic illustration that shows a silver particle that has a spherical shape.

FIG. 3B is a schematic illustration that shows a silver particle that has a flake shape.

FIG. 4 is a schematic plan-view illustration of a core-shell particle, according to an embodiment of the invention.

FIG. 5 is a SEM image of a film that resulted from firing a paste that contained silver microparticles and nondeformable inorganic material particles.

FIG. 6 is a SEM image of a film that resulted from firing a paste that contained silver nanoparticles and nondeformable inorganic material particle, according to an embodiment of the invention.

FIG. 7 is a schematic drawing that shows the rear side of a silicon solar cell.

FIG. 8 is a schematic drawing that shows the front (or illuminated) side of a silicon solar cell.

FIG. 9 is a schematic cross-section drawing that shows an embodiment of metallization layer on the front face of a solar cell.

FIG. 10 is a schematic cross-section drawing that shows another embodiment of metallization layers on the front face of a solar cell.

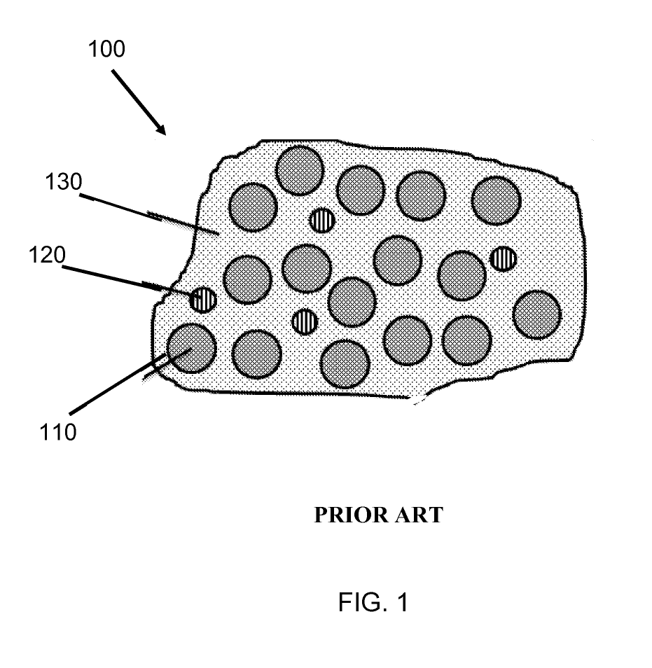

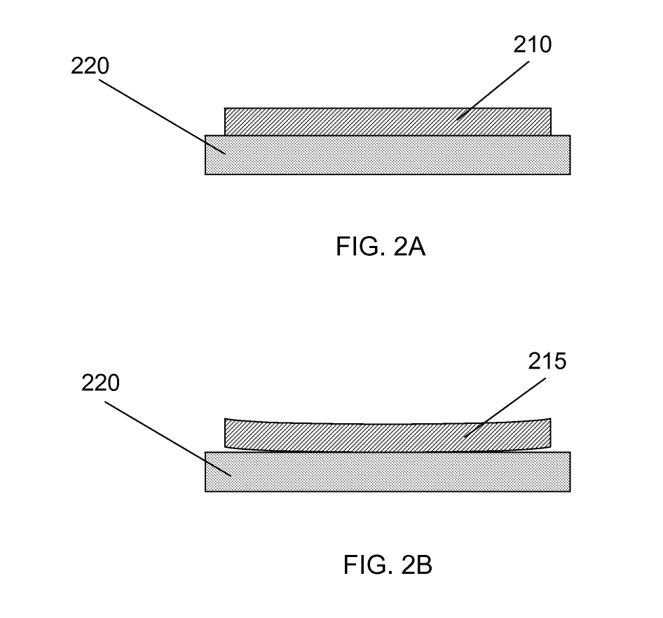

### SUMMARY

An electrode metallization paste is disclosed. The paste contains a plurality of silver particles that make up between 10 wt % and 50 wt % of the paste. More than 50 wt % of the silver particles are nanoparticles that have a D50 diameter between 10 nm and 1000 nm. The nanoparticles are configured to deform upon firing at temperatures greater than 500° C. Less than 50 wt % of the silver particles are microparticles with at least one dimension greater than 1000 nm. The paste also contains a plurality of nondeformable inorganic material particles that make up more than 10 wt % of the paste and glass frit. The silver particles, the nondeformable inorganic material particles, and the glass frit are all mixed together in an organic vehicle. Such pastes will be herein referred to as “silver nanoparticle pastes” due to their notably high silver nanoparticle component versus conventional thick film metallization pastes.

In one arrangement, the metallization paste has a viscosity between 10,000 and 200,000 cP at 25° C. and at a sheer rate of 4 sec⁻¹. In one arrangement, the metallization paste has a solids loading between 30 wt % and 70 wt %. The nondeformable inorganic material particles may be made of a metal such as nickel (Ni), cobalt (Co), aluminum (Al), boron (B), phosphorus (P), or alloys thereof. The nondeformable inorganic material particles may be made of a material such as aluminum (Al), tin (Sn), zinc (Zn), lead (Pb), antimony (Sb), nickel (Ni), boron (B), phosphorus (P), magnesium (Mg), molybdenum (Mo), manganese (Mn), tungsten (W), or alloys, composites, or other combinations thereof. In one arrangement, the nondeformable inorganic material particles may be made of copper (Cu). The nondeformable inorganic material particles may be made of an oxide that includes at least one element such as silicon (Si), boron (B), nickel (Ni), cobalt (Co), aluminum (Al), molybdenum (Mo), manganese (Mn), tungsten (W), chromium (Cr), tin (Sn), zinc (Zn), lead (Pb), or antimony (Sb). The nondeformable inorganic material particles may be core-shell particles that have an outer shell made of a nondeformable inorganic material such as any of those described herein.

In various arrangements, the silver nanoparticles have a D50 that is between 10 nm and 500 nm, between 10 nm and 300 nm, between 10 nm and 200 nm, or between 10 nm and 100 nm. In some arrangements, the silver nanoparticles have a D50 range between 100 nm and 800 nm, between 150 nm and 500 nm, or between 150 nm and 300 nm.

In various arrangements, the nondeformable inorganic material particles have a D50 range between 200 nm and 1000 nm, between 500 nm and 1000 nm, or between 750 nm and 1000 nm.

In yet other arrangements, the nondeformable inorganic material particles have a D50 range between 200 nm and 2500 nm, between 500 nm and 2000 nm, or between 750 nm and 1500 nm.

In one embodiment of the invention, the metallization paste comprises 40 wt % silver nanoparticles, 11 wt % silver microparticles, 21 wt % nondeformable inorganic material particles, 3 wt % glass frit, and 25 wt % organic vehicle.

In another embodiment of the invention, the metallization paste comprises 33 wt % silver nanoparticles, 9.5 wt % silver microparticles, 17.5 wt % nondeformable inorganic material particles, 2 wt % glass frit, and 38 wt % organic vehicle.

In another embodiment of the invention, the metallization paste comprises 33 wt % silver nanoparticles, 0 wt % silver microparticles, 27 wt % nondeformable inorganic material particles, 1 wt % glass frit, and 39 wt % organic vehicle.

In another embodiment of the invention, the metallization paste comprises 21 wt % silver nanoparticles, 4 wt % silver microparticles, 25 wt % nondeformable inorganic material particles, 3 wt % glass frit, and 47 wt % organic vehicle.

In another embodiment of the invention, the metallization paste comprises 12 wt % silver nanoparticles, 3 wt % silver microparticles, 35 wt % nondeformable inorganic material particles, 4 wt % glass frit, and 46 wt % organic vehicle.

In another embodiment of the invention, the metallization paste comprises 40 wt % silver nanoparticles, 8 wt % silver microparticles, 37 wt % nondeformable inorganic material particles, 5 wt % glass frit, and 10 wt % organic vehicle.

A method for using a metallization paste is described herein. The method involves applying or printing (e.g., screen printing or inkjet printing) the metallization paste onto at least a portion of a surface of a substrate. In one arrangement, the metallization paste contains a plurality of silver particles that make up between 10 wt % and 50 wt % of the paste. More than 50 wt % of the silver particles are nanoparticles that have a D50 between 10 nm and 1000 nm. The nanoparticles are configured to deform upon firing at temperatures greater than 500° C. Less than 50 wt % of the silver particles are microparticles with at least one dimension greater than 1000 nm. The paste also contains a plurality of nondeformable inorganic material particles that make up more than 10 wt % of the paste and glass frit. The silver particles, the nondeformable inorganic material particles, and the glass frit are all mixed together in an organic vehicle to form the paste. More specific paste formulations, as described above, may also be used in this method.

After the paste is applied, the substrate is heated to between 100° C. and 250° C. for between 10 and 900 seconds to dry the metallization paste. Then the substrate is fired to a peak firing temperature between 650° C. and 900° C. to form a metallization film.

The substrate may be a silicon solar cell. The metallization paste may be applied to form fine grid lines on the front surface of the silicon solar cell. The metallization paste may be applied to form front busbars on the front surface of the silicon solar cell. The metallization paste may be applied to form floating busbars on the front surface of the silicon solar cell. The metallization paste may be applied to form rear tabbing structures on the back surface of the silicon solar cell.

In one arrangement, the metallization film has a porosity less than 40%. The metallization film may have a density greater than 6 g/cm³. The metallization film may have a resistivity between 3.0×10⁻⁸ and 1.5×10⁻⁷ ohm-cm². The metallization film may have a thickness between 3 and 10 microns. In one arrangement, the metallization film has a peel strength between 1 and 3 N/mm when soldered using a flux and tabbing ribbon. The metallization film may alternately have a peel strength greater than 1 N/mm, greater than 1.5 N/mm, or greater than 2 N/mm when soldered using a flux and tabbing ribbon.

In another embodiment of the invention, a solar cell has a silicon substrate that has a plurality of fine grid lines on its front surface. There is at least one front busbar layer on the front surface of the silicon substrate, and the front busbar layers are in electrical contact with the plurality of fine grid lines. There are an aluminum layer and at least one rear tabbing layer on the back surface of the silicon substrate. At least one of the plurality of fine grid lines, the front busbar layer, or the rear tabbing layer has a condensed particle morphology that consists of nondeformable inorganic material particles dispersed in a silver matrix, such that the weight ratio of silver to nondeformable inorganic material particles is about 5:1. The nondeformable inorganic material particles (NIMPs) comprise aluminum (Al), tin (Sn), zinc (Zn), lead (Pb), antimony (Sb), nickel (Ni), boron (B), phosphorus (P), magnesium (Mg), molybdenum (Mo), manganese (Mn), tungsten (W), and alloys, composites, or other combinations thereof.

When the rear tabbing layer has the condensed particle morphology described above, it has a peel strength of more than 1 N/mm when soldered to tin coated copper tabbing ribbons using tin based solders and fluxes. The rear tabbing layer may have a thickness between 3 and 10 μm. The rear tabbing layer may have a conductivity that is 2 to 10 times less than the conductivity of bulk silver.

When the front busbar layer has the condensed particle morphology described above, it has a peel strength of more than 1 N/mm when soldered to tin coated copper tabbing ribbons using tin based solders and fluxes. The front busbar layer may have a thickness between 3 μm and 15 μm or between 3 μm and 50 μm. The front busbar layer may have a conductivity that is 2 to 10 times less than the conductivity of bulk silver. The front busbar layers may be parallel to one another. The distance between the front busbar layers may be less than 4 cm.

In one arrangement, the front surface of the silicon substrate has an anti-reflective coating, and the front busbar layers do not penetrate through the anti-reflective coating and do not make electrical contact to the silicon substrate. In another arrangement, the front surface of the silicon substrate has a silicon emitter layer, and the front busbar layer makes electrical contact to the silicon emitter layer.

The fine grid lines may have the condensed particle morphology described above. The fine grid lines may have a thickness between 20 μm and 50 μm. The solar fine grid lines may have a conductivity that is 1.5 to 7 times less than the conductivity of bulk silver.

In one arrangement, the front surface of the silicon substrate has a silicon emitter layer, and the fine grid lines make electrical contact to the silicon emitter layer with a contact resistance less than 100 mohm-cm².

In one arrangement, there is an additional metal layer between the fine grid lines and the silicon substrate. In another arrangement, there is an additional metal layer over the fine grid lines. Such additional metal layers may be silver.

### DETAILED DESCRIPTION

The preferred embodiments are illustrated in the context of metallizations for silicon-based solar cells. The skilled artisan will readily appreciate, however, that the materials and methods disclosed herein will have application in a number of other contexts where making good electrical contact to semiconducting or conducting materials is desirable, particularly where good adhesion and low cost are important.

These and other objects and advantages of the present invention will become more fully apparent from the following description taken in conjunction with the accompanying drawings.

### DEFINITIONS

The term “nanoparticle” is used herein to mean particles with a D50 that is greater than 1 nm and less than 1000 nm. D50 is a common metric that is used to define the median diameter of particles; the D50 value is defined as the value where half of the particle population has a diameter below and half the particle population has a diameter above the value. D10 is the value where 10% of the volume of the population is below the value and D90 is where 90% of the volume of the population is below the value. Measuring particles smaller than one micron is typically performed with a laser particle size analyzer such as the Horiba LA-300. As an example, spherical particles are dispersed in a solvent in which they are well separated and the scattering of transmitted light is directly correlated to the size distribution from smallest to largest dimensions. The most common approach to express laser diffraction results is to report the D10, D50, and D90 values, which are based on volume distributions. In various embodiments, more specific ranges are given for the dimensions of nanoparticles. Various shapes of nanoparticles are included within the definition, and their dimensions are specified herein.

The term “nondeformable inorganic material particle” (NIMP) is used herein to mean any particle that, when used in a paste with glass frits, experiences little or no change at glass flowing temperatures (approximately 500° C.-800° C.).

The term “solids loading” is used herein to mean the amount or proportion of solids in a metallization paste. The solids include silver particles, nondeformable inorganic material particles (NIMPs), and frit.

The D10 and D90 values also give an indication of the polydispersity of the nanoparticles measured. While low polydipersity is important for tight packing of systems with two different particle sizes, it is less important for nanoparticle systems, where the D50 of the nondeformable inorganic material particles may be as much as four times greater than the D50 of the silver nanoparticles.

The term “porosity” used herein to mean the percentage of a film's volume that is empty space as compared to the total film volume. The porosity can be measured by comparing the weighted density average for the given solids loading (e.g., silver, NIMP, and frit composition) versus the measured density, which can be obtained by dividing the fired film weight by the film volume (i.e., the fired film thickness, as measured by scanning electron microscopy or atomic force microscopy, times the print area).

Throughout this disclosure, pastes containing silver nanoparticles, silver microparticles, and NIMPs will be referred to as silver nanoparticle pastes.

### Metallization Pastes in Solar Cells

Metallization pastes are used to form three different layers on the solar cell: rear tabbing, fine grid lines, and front busbars. These layers have different materials properties that fall into four primary categories:
solderability
peel strength,
resistivity of ohmic contact to silicon, and
conductivity.

Solderability is the ability to form a strong physical bond between two metal surfaces by the flow of a molten metal solder between them at temperatures below 400° C. All soldering on a solar cell is performed after heating in air to over 750° C. for approximately one second, and the term, “high-temperature solderability,” is used herein to mean the ability to be soldered after heating to over 750C in air. High-temperature solderability has a stricter standard than solderability and precludes the use of metals which form thick layers of oxide on heating to 750C. High-temperature solderability involves the use of flux, which is any chemical agent that cleans or etches one or both of the surfaces prior to reflow of the molten solder. This becomes even more difficult because many metal oxides are resistant to commonly used fluxes after oxidation above 750C.

For layers that directly contact a tabbing ribbon, it is useful if the peel strength is greater than 1 N/mm (Newton per millimeter). The peel strength is defined as the force required to peel a soldered ribbon, at a 180° angle from the soldering direction, divided by the width of the soldered ribbon. It is common for the peel strength to be between 1.5 and 3 N/mm on contacts to the tabbing ribbons in commercially available solar cells. Peel strength is a metric of solder joint strength for solar cells.

The conductivity of a solar cell is determined by directly measuring the resistance of individual layers on the solar cell. Meier et al. describes how to use a four-point probe electrical measurement to determine the resistivity of each metallization layer (Reference: Meier et al. “Determining components of series resistance from measurements on a finished cell”, IEEE (2006) pp1315). Because Ag based metallization layers are relatively compact (i.e., have low porosity) the bulk resistivity of the metallization layer is often considered a more useful metric than the actual resistivity of the metallization layers themselves. However, for some types of metallization pastes, the films do not completely compact. Thus the bulk resistivity may not provide an accurate comparison between different types of metallization pastes with the same printed thickness, and it is best to measure the resistance of individual layers in the method described by Meier et al. for an accurate comparison. When describing the difference in resistivity between nickel and silver based metallization layers we are implying the absolute lowest ratio whether comparing the bulk resistivity or the measured total resistivity of the individual layer as measured using the four-point probe method described by Meier et al. Ohmic contact resistivity is a measure of the contact resistivity between the fired metal film and the silicon surface. The contact resistivity can be measured by TLM (transfer length method) and is in the range of 1 to 100 mΩ-cm².

Currently about 75% of all the silver used on a solar cell is in the silver paste on the front of the silicon substrate (the side exposed to sunlight) as fine grid lines and busbars; the remaining 25% is used on the back side as the rear tabbing layer. State-of-the-art front side metallization pastes contain silver, glass frit, binder, and a solvent. Some example pastes contain over 80 wt % pure silver particles. The paste mixtures are formulated to be printed directly onto solar cells via screen printing, subsequently dried, and then fired in an oxidizing ambient to vaporize and oxidize organic molecules in order to achieve higher electrical conductivity. In some examples, the front busbar and fine grid line layers are deposited during the same screen printing step.

The purpose of the fine grid lines is to collect current from the front side of the solar cell and transport it to the busbars. Thus it is important to use highly conductive materials (e.g., silver) for fine grid lines. This is especially important when using two or three busbar architectures, as the distance over which the current travels in the fine grid lines before reaching a busbar can be greater than one centimeter. Even when the fine grid lines are silver, approximately 75% of the total series resistance of a solar cell with a two busbar architecture comes from current flowing through the fine grid lines.

Upon firing the front side, the silver paste is designed to condense with a minimum amount of voids and to achieve a bulk resistivity that is 1.2-1.5 times the bulk resistivity of pure silver (1.5E-8 ohm-m). The front side silver paste is also designed to print with a high aspect ratio to form fine grid lines that are 20-60 μm wide and 20-50 μm high. Reducing the width of the grid lines can improve the light absorption of the PV cell by exposing more silicon to sunlight. Increasing the height of the fine grid lines can further reduce the series resistance. Fine grid lines also form ohmic contacts with silicon; it is useful if the ohmic contacts have a resistance less than about 100 mΩ-cm². It should be noted that the fine grid lines are not physically connected to the tabbing ribbon, so solderability and peel strength are not important metrics for fine grid lines.

The purpose of the busbars is quite different. The busbars make ohmic contact to both the fine grid lines and the tabbing ribbon. It is important that the front busbar layer is high-temperature solderable and adheres well to the front side of the solar cell. The front busbars transfers current from the fine grid lines to the copper tabbing ribbon to connect multiple solar cells in a module. Importantly, current transport occurs vertically through the thickness of a continuously tabbed busbar layer, which is 10-20 μm thick, and not laterally as in the case of the fine grid lines. Therefore, though it may be non-obvious, busbars can have a bulk conductivity that is less than 100 times that of silver without impacting solar cell performance significantly. It is useful if the front busbar layer has a peel strength greater than 1 N/mm after it is soldered to the tabbing ribbon.

In current PV cell architectures, the busbar and fine grid lines are printed at the same time using the same front side metallization paste. After both layers are dried, they are fired at the same conditions as described above, at which time they partially decompose the silicon nitride (anti-reflective) layer and make electrical contact to the underlying silicon. The busbars make ohmic contact to the silicon with a contact resistance less than 100 mΩ-cm².

In some cases floating busbars are desirable. A floating busbar is a busbar that does not make significant direct electrical contact to the silicon but only to the fine electrical grid lines on the front side of the silicon solar cell. This means that the contact resistivity between the fired floating metal busbar and the silicon surface exceeds 0.1 Ω-cm². For such busbars, metal pastes that do not fully penetrate through the anti-reflective coating after firing are formulated.

To date, attempts to reduce silver usage on the front side of silicon solar cells have involved completely redesigning the front contact deposition method and changing the process flow. One recently implemented method is the sequential electroplating of layers of nickel, copper, and silver to form a multilayer grid. This process requires laser scribing through the silicon nitride anti-reflective coating to expose the surface of the silicon emitter region followed by electroplating base metals to form fine grid lines and busbars. First a thin nickel layer is electroplated to promote adhesion to silicon. Then a thicker conductive copper layer is electroplated onto the nickel layer. Then the stack is capped with a thin silver layer for soldering to the copper tabbing ribbon. This approach requires new, non-standard, processing steps and equipment. In addition, such a stack may not be resilient against temperature fluctuations during regular use of the solar cell, which could lead to copper oxidation and copper diffusion into the silicon. Copper diffusion is especially problematic because it can cause local shunting through the emitter region. One other problem with this approach is that as nickel reacts with silicon a nickel silicide may form. The emitter region of the solar cell is thin (e.g., 50-500 nm), and there is a risk that the nickel silicide may consume the entire emitter layer and shunt the solar cell. These problems, in addition to capital expenditures and waste disposal requirements, have limited the adoption of electroplating processes in silicon solar cell manufacturing.

The purpose of the rear tabbing layer is to make ohmic contact to an Al layer on the back side of the silicon. The Al layer collects current from the rear side of the solar cell. It is useful if the rear tabbing layer is high-temperature solderable and adheres well to the silicon. The rear tabbing layer is soldered to the copper tabbing ribbon in order to transport current from the rear side of the solar cell to the tabbing ribbon. Importantly, current transport occurs vertically through the thickness of the rear tabbing layer, which is 3-10 μm thick, and not laterally as in the case of the fine grid lines, as discussed above. Therefore, though it may be non-obvious, rear tabbing layers can have a bulk conductivity that is less than 100 times that of silver without impacting solar cell performance significantly. In general, the rear tabbing layer does not make ohmic contact to the rear side of the solar cell. It is useful if the rear tabbing layer has a peel strength greater than 1 N/mm after it is soldered to the tabbing ribbon.

An alternative paste for use in solar cell metallization layers has been developed. The alternative paste has both silver nanoparticles and nondeformable inorganic material particles. Unlike previous attempts to employ nondeformable materials in metallization pastes, the formulations described herein can be used to form metallization layers that have good characteristics and are highly robust for film thicknesses greater than 500 nm. Such metallization layers can be fired at temperatures of 750° C. and greater, have good solderability and peel strength, make low resistance ohmic contacts to silicon and are highly conductive. The addition of silver nanoparticles to alternative metallization pastes provides better particle compaction during firing. But care must be taken to add just the right amount of silver nanoparticles as too high a proportion of nanoparticles can cause mechanical failure during drying or firing, as discussed above. An optimum proportion of silver nanoparticles combined with nondeformable inorganic material particles yields films excellent compaction after firing, even at high temperatures, making such films ideal for use in solar cell applications.

State-of-the-art silver rear tabbing metallization pastes contain a mixture of micron-sized spherical and flake silver particles with a small amount of silver nanoparticles (e.g., less than 20% of the total silver weight). Such pastes print films that have a relatively low density upon drying, but compact by as much 40-50% during firing to form dense, strong films. Thus it is clear from experience with silver metallization films that merely increasing the proportion of nano- versus micro-silver particles does not improve the overall peel strengths of the resulting films. On the contrary, increasing the silver nanoparticle content in such films can result in reduced film quality and lower peel strengths.

Supplementing such state-of-the-art silver metallization pastes with nondeformable inorganic material particles disrupts film compaction; mixed Ag/nondeformable particle systems typically compact by less than 20% upon firing. Such films can have densities that are less than the densities of pure Ag films, resulting in concomitant lower peel strengths. It should be noted that when deformable, micron-sized Ag particles of various shapes are mixed with nondeformable, non-Ag, micron-sized particles in metallization pastes, the films that result are porous, do not compact well and may become even more porous after firing. Such films often have significantly lower peel strengths when soldered to tabbing ribbons than do state-of-the-art silver pastes. Although many efforts have been made to reduce the silver content of metallization pastes in order to reduce costs, it has been shown that when nondeformable inorganic material particles are substituted for some of the silver content, poor quality films result.

Based on experience with state-of-the-art silver metallization pastes, films with unacceptably poor qualities result when nondeformable inorganic material particles are substituted for silver microparticles or when the proportion of silver nanoparticles (vs. silver microparticles) is increased. Surprisingly, a new metallization paste has been developed that uses both nondeformable inorganic material particles and increased silver nanoparticle loading to great advantage. Films made from the new metallization paste yield metallization films with peel strengths between 1 and 4 N/mm and at lower cost than state-of-the-art pastes.

In one embodiment of the invention, a rear tabbing and front busbar silver nanoparticles metallization paste includes the following components:
a. particles (between 30 and 70 overall wt %);
   silver nanoparticles (between 10 and 40 overall wt %)
   silver microparticles (between 0 and 10 overall wt %);
   nondeformable inorganic material particles (between 10 and 60 overall wt %);
b. glass frit (between 0.1 and 6 overall wt %); and
c. an organic vehicle (between 25 and 60 overall wt %).

In another embodiment of the invention, a front side or fine grid line silver nanoparticles metallization paste includes the following components:
a. particles (between 75 and 90 overall wt %);
   silver nanoparticles (between 10 and 70 overall wt %)
   silver microparticles (between 0 and 25 overall wt %);
   nondeformable inorganic material particles (between 10 and 80 overall wt %);
b. glass frit (between 0.1 and 6 overall wt %); and
c. an organic vehicle (between 10 and 25 overall wt %).

In one arrangement, the silver nanoparticles have a D50 between about 10 nm and 1000 nm. The silver nanoparticles may have a D50 that is less than 1000 nm, or less than 500 nm, or less than 300 nm, or less than 200 nm, or less than 100 nm, or any range therein. In one arrangement, the silver nanoparticles have a D50 that is between 100 nm and 800 nm, or between 150 nm and 500 nm, or between 150 nm and 300 nm, or any range therein. In an exemplary embodiment, silver nanoparticle powders are spheres with a D50 of 100 nm, a D10 of 50 nm, and a D90 of 300 nm. In another exemplary embodiment, silver nanoparticle powders are spheres with a D50 of 200 nm, a D10 of 100 nm, and a D90 of 500 nm. In another exemplary embodiment, silver nanoparticle powders are spheres with a D50 of 250 nm, a D10 of 100 nm, and a D90 of 350 nm. It should be noted that the polydispersity (i.e., D10 and D90) of nanoparticle powders can vary significantly depending on the synthesis technique and the supplier. There are several D10 and D90 levels that can result in acceptable compact films.

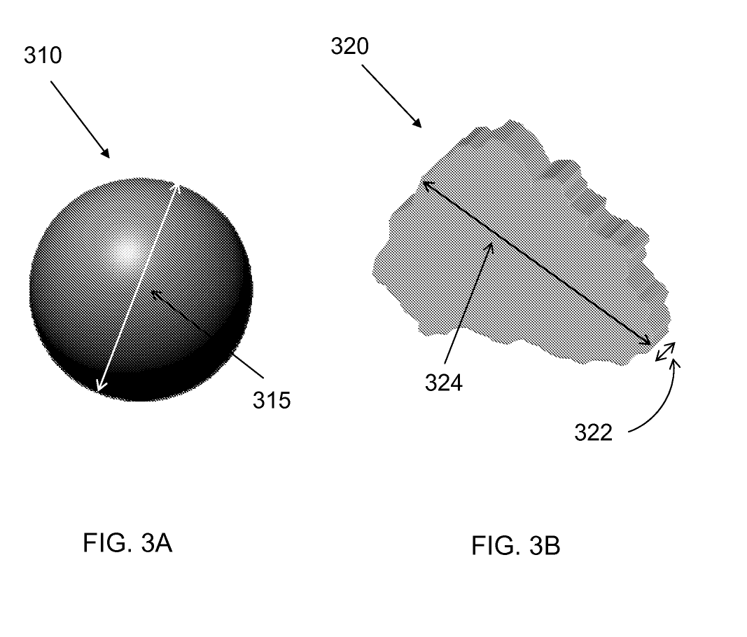

An example of a spherical silver particle 310 is shown in FIG. 3A. Such a particle has only one dimension, a diameter, indicated by 315. The sphere 310 is shown to illustrate a shape that is equiaxed—one whose largest dimension and smallest dimension are the same. It is unlikely that silver particles would take on such a perfect shape 310, but shapes that are approximately equiaxed are possible within the embodiments of the invention. In one arrangement, silver nanoparticles have a D50 diameter 315 between 10 nm and 1000 nm. In one arrangement, silver microparticles have at least one dimension greater than 1000 nm. It should be noted that it is not necessary for the nanoparticles to have a spherical shape. In some instances, non-spherical particles, which have higher surface areas and may have depressed melting temperatures may be more desirable.

An example of a flake particle 320 is shown in FIG. 3B. The flake 320 has a smallest dimension given by its thickness 322 and a largest dimension indicated by 324. Again, it is unlikely that silver particles would take on such a perfectly planar shape, but approximations to this are possible within the embodiments of the invention. In one arrangement, flake particles have largest dimensions 324 that are greater than 1000 nm and can be described as microparticles.

The shapes in FIGS. 3A and 3B are given as illustrative examples only and are not meant to restrict, in any way, the possible shapes that silver particles can have within the dimensional limits outlined above.

Silver particles (both nano- and micro-) deform when fired at temperatures greater than 700° C. Deformation is a result of the interaction of the silver particles with heavy metal-containing glass frits at firing temperatures above the glass transition temperature of the glass frit. At such temperatures, the flowing glass enables rapid diffusion, sintering, and reorganization of the silver particles in a manner that resembles melting. The morphology of films made with pastes that include such particles has reduced void space after firing due to settling and coalescence of silver as the glass flows.

A third particle component in the paste is a nondeformable inorganic material particle (NIMP). Such particles are not highly soluble in glass frit and experience little or no change at glass flowing temperatures, which are between about 500° C. and 800° C. In one embodiment, the nondeformable particles contain a homogeneous material that has a melting point higher than 800° C. and that is chemically inert to the glass. In another embodiment the nondeformable particles have a composite core-shell morphology, with an inert shell surrounding a melting or glass-interacting material, such that the overall particle acts as a nondeformable material at glass-flowing temperatures. Examples of nondeformable inorganic material particles include pure or coated particles of aluminum (Al), tin (Sn), zinc (Zn), lead (Pb), antimony (Sb), nickel (Ni), boron (B), phosphorus (P), magnesium (Mg), molybdenum (Mo), manganese (Mn), tungsten (W), and alloys, composites, or other combinations thereof. In one arrangement, the nondeformable inorganic material particles may be made of copper (Cu). Additionally, nondeformable inorganic materials also include compounds of oxygen with at least one element such as silicon (Si), boron (B), nickel (Ni), cobalt (Co), aluminum (Al), molybdenum (Mo), manganese (Mn), tungsten (W), chromium (Cr), tin (Sn), zinc (Zn), lead (Pb), or antimony (Sb). In some arrangements, the nondeformable inorganic material particles contain no Ag. It is especially useful if care is taken to ensure that there is chemical compatibility between the NIMPs and the glass fits in the pastes.

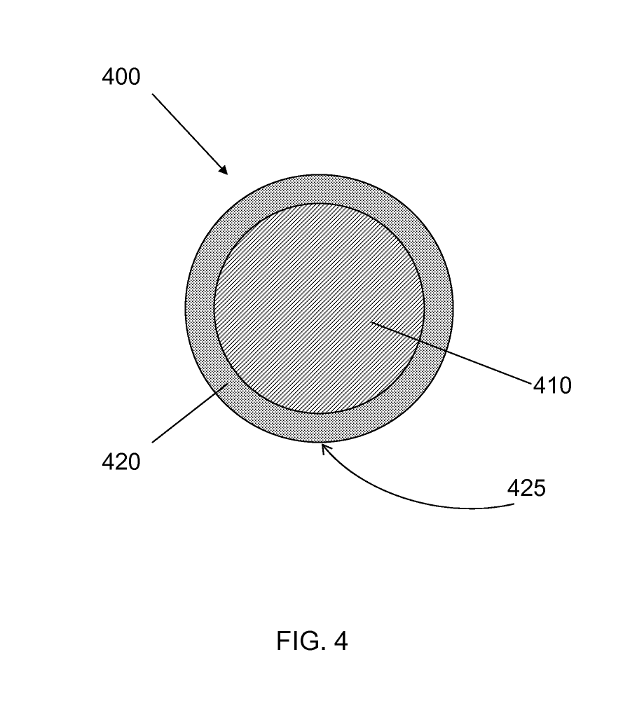

FIG. 4 is a schematic drawing of a core-shell or coated nondeformable inorganic material particle 400, according to an embodiment of the invention. There is a core particle 410 that is surrounded by a first shell 420. The outer surface 425 of the shell 420 is also indicated. The core particle 410 may be made of any of the metals or alloys listed above. The first shell 420 may be made of any nondeformable inorganic material listed above.

One route to improve flow of silver nanoparticles around nondeformable inorganic material particles is to coat the nondeformable inorganic material particles with silver. The silver coating can be non-conformal such as with silver nanoparticle decoration or conformal such as with a thin silver shell formed, for example, by a reduction reaction. Nanoparticle decoration is a technique known to one skilled in the art by which small silver nanoparticles, with diameters between 1 and 50 nm, can be attached in a single or multiple layers onto other larger particles. Coating nondeformable inorganic material particles with silver also introduces ligands similar to those on commercially available silver nanoparticles onto the surfaces of the nondeformable inorganic material particles, thus ensuring similar levels of dispersion in the organic vehicle. In an exemplary embodiment, nondeformable inorganic nickel particles are coated first with a shell of nickel boron and then with a conformal shell of silver using industrial standard practices.

In some arrangements, the nondeformable inorganic material particles include a mixture of possible particles, such as particles of different metals and alloys or particles of both metals and alloys and particles of oxygen compounds.

In one arrangement, the nondeformable inorganic material particles have a D50 between about 200 nm and 2500 nm. The nondeformable inorganic material particles may have a D50 that is less than 2500 nm, or less than 2000 nm, or less than 1500 nm, or less than 1000 nm, or less than 500 nm, or any range therein. In one arrangement, the nondeformable inorganic material particles have a D50 that is between 500 nm and 2000 nm, or between 750 nm and 1500 nm, or any range therein. In an exemplary embodiment, nondeformable inorganic material particles are spheres with a D50 of 500 nm, a D10 of 200 nm, and a D90 of 1000 nm. In another exemplary embodiment, nondeformable inorganic material particle powders are spheres with a D50 of 1000 nm, a D10 of 600 nm, and a D90 of 2000 nm. In another exemplary embodiment, nondeformable inorganic material particle powders are spheres with a D50 of 2500 nm, a D10 of 1200 nm, and a D90 of 4000 nm. It should be noted that the polydispersity (i.e., D10 and D90) of nanoparticle powders can vary significantly depending on the synthesis technique and the supplier. There are several D10 and D90 levels that can result in acceptable compact films.

The silver nanoparticles, silver microparticles, and nondeformable inorganic material particles are all mixed together with a glass frit and an organic vehicle (that also contains a binder) to form a paste. In one arrangement, the paste is suitable for screen printing. In another arrangement, the paste is suitable for inkjet printing. In various embodiments of the invention, the total solid component of the paste, including all particles is between 30 wt % and 90 wt %, or between 30 wt % and 75 wt %, or between 40 wt % and 60 wt %, or any range therein. In various arrangements, the paste has a viscosity between 10,000 and 200,000 cP as measured by a viscometer at 25° C. and at a shear rate of 4 sec⁻¹ for screen printable paste or between 1 and 10,000 cP for inkjet printable pastes, or any range therein.

In many embodiments, films resulting from the firing of silver nanoparticle metallization pastes are called Ag/NIMP composite layers or films. In some embodiments of the invention, films made from firing the metallization pastes disclosed herein have porosities less than 40%, less than 30%, less than 20%, or less than 10%. In some embodiments of the invention, films made from the metallization pastes disclosed herein have densities greater than 6 g/cm³, greater than 7 g/cm³, greater than 8 g/cm³, or greater than 9 g/cm³, or any range therein. In one arrangement, the metallization film has a resistivity between 3.0×10⁻⁸ and 1.5×10⁻⁷ ohm-cm², or any range therein.

Some exemplary silver nanoparticle metallization paste formulations are given in Table I below.

TABLE I
Exemplary Silver Nanoparticle Metallization Paste Formulations

| | | | Nondeformable | | |
|---|---|---|---|---|---|
| | Silver | Silver | inorganic material | | Organic |
| Paste Use (lines) | nanoparticles | microparticles | particles | Glass frit | vehicle |
| Rear | 40 wt % | 11 wt % | 21 wt % | 3 wt % | 25 wt % |
| Tabbing/Busbar | | | | | |
| Rear | 33 wt % | 9.5 wt % | 17.5 wt % | 2 wt % | 38 wt % |
| Tabbing/Busbar | | | | | |
| Rear | 33 wt % | 0 wt % | 27 wt % | 1 wt % | 39 wt % |
| Tabbing/Busbar | | | | | |
| Rear | 21 wt % | 4 wt % | 25 wt % | 3 wt % | 47 wt % |
| Tabbing/Busbar | | | | | |
| Rear | 12 wt % | 3 wt % | 35 wt % | 4 wt % | 46 wt % |
| Tabbing/Busbar | | | | | |
| Front Side/Fine Grid | 40 wt % | 8 wt % | 37 wt % | 5 wt % | 10 wt % |

The remaining non-silver portions of the metallization pastes are made up of organic vehicle and glass frit. Commercially available glass frit (e.g., Ceradyne product #V2027) and other additives can be used in front side metallization pastes to penetrate through anti-reflective coatings, improve silver sintering, and make ohmic contact to doped silicon. Glass frit may be a mixture of the oxides of bismuth, zinc, tellurium, sodium, lithium, lead, and silicon, with the final ratios and compositions varied to achieve a melting point between 500° C. and 800° C. The doping density of the emitter region in the silicon and the additives in the metallization pastes can be adjusted relative to one another to optimize electrical contact. The organic vehicle is a mixture of organic solvents and binders. Organic vehicle can be adjusted depending on the exact paste deposition conditions. The viscosity of metallization pastes can be tuned by adjusting the amounts of organic binders and solvents in organic vehicle and by including thixotropic additives, organic binders, and solvents. In this way, various pastes can be made to apply coatings that can range in fired thickness between about 3 and 10 μm or between 3 and 15 μm (e.g., for rear tabbing and front busbar layers) and between about 20 and 50 μm (e.g., for front side or fine grid lines). It should be noted that it is possible to make much thicker films by printing again and again over previously-printed lines. Common coating solvents include terpineol and the family of glycol ethers (diethylene glycol monobutyl ether, triethylene glycol monobutyl ether, and texanol). Common organic binders include ethyl cellulose, carboxymethyl cellulose, poly(vinyl alcohol), poly(vinyl butyral), and poly(vinyl pyrrolidinone).

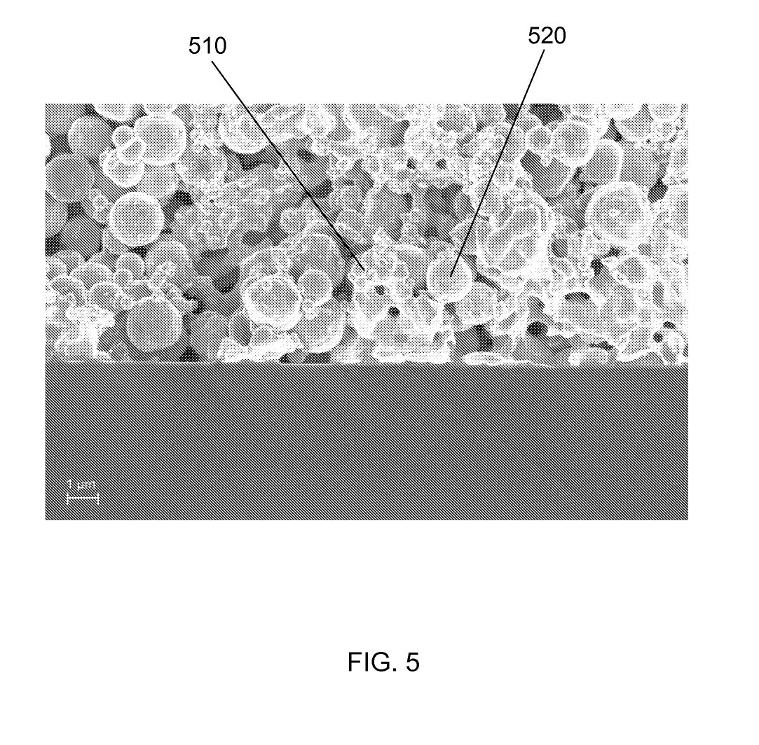

A first metallization paste was made from a silver/nondeformable inorganic material particle paste where silver content in the paste contained a majority (by weight) of micron-sized particles (i.e., silver flake and 1 um sized spheres). The paste was applied to a silicon wafer and fired in a rapid thermal annealer to a peak firing temperature of 800° C. FIG. 5 is a SEM image of the resulting film. As can be seen in FIG. 5, the film is relatively porous. The micron sized Ag particles 510 do not completely surround the nondeformable inorganic particles 520. Some NIMPs are found to be completely unconnected to the silver matrix, and pores greater than 100 nm at their smallest dimension can be easily distinguished. Furthermore, silver regions are separated by between 500 nm and 5 μm from, forming a matrix with large nodes and low connectivity. Porosities for films formed from such alternate metallization pastes are 30% to 50%. Such films had peel strengths that were less than 1.5 N/mm.

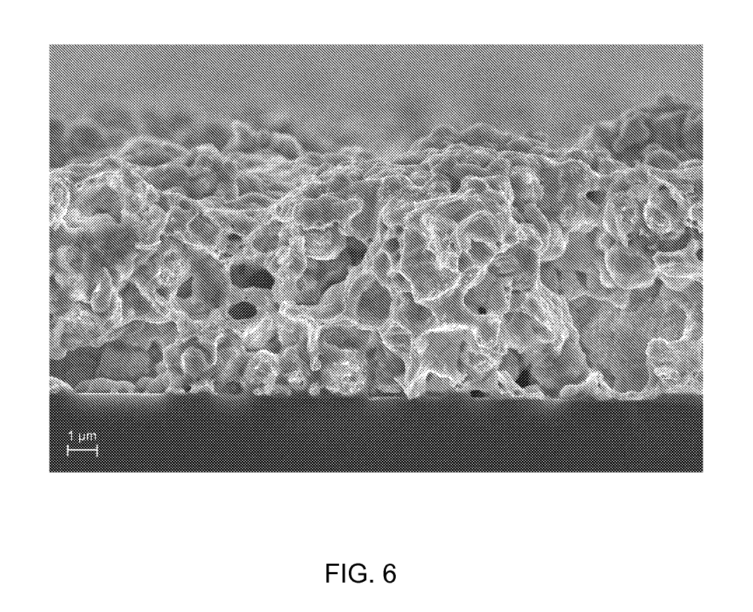

A second metallization paste was made from a nanosilver/nondeformable inorganic material particle paste where silver content in the paste contained a majority (by weight) of nanoparticles, according to an embodiment of the invention. The paste was applied to a silicon wafer and fired in a rapid thermal annealer to a peak firing temperature of 800° C. FIG. 6 is a SEM image of the resulting film. As can be seen in FIG. 6, the film is densely packed with low apparent porosity. It is difficult to distinguish individual nondeformable inorganic material particles as the silver particles have covered them extensively. The silver matrix connects in many points around the NIMPs, with small nodes and high connectivity. Fired films resulting from silver nanoparticle pastes commonly have porosities which are between 15% and 35%. Such films had peel strengths that were more than 4 N/mm.

The films shown in FIG. 5 and FIG. 6 are made from pastes that have similar solids loadings (70-75 wt %), frit concentrations (2-3 wt %), and silver to nondeformable inorganic particle weight ratios (70:30). However, because of the high loading of silver nanoparticles in the paste in FIG. 6, the film is more dense and has significantly higher peel strength.

### Solar Cell Fabrication Using Silver Nanoparticle Rear Tabbing Pastes

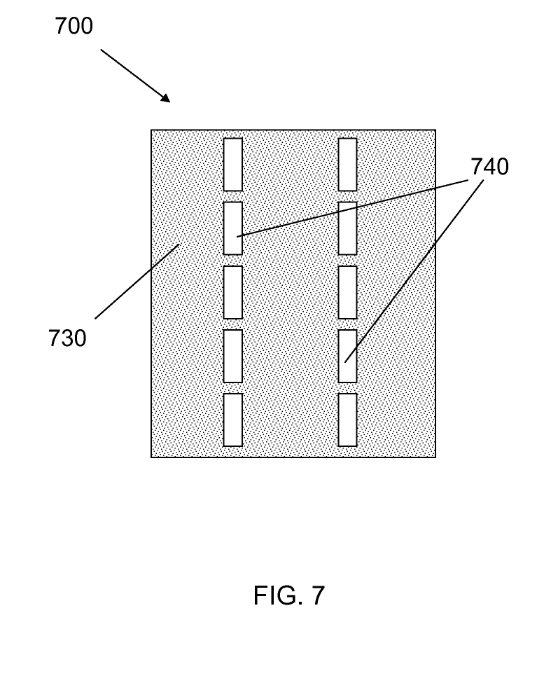

FIG. 7 is a schematic drawing that shows the rear side of a silicon solar cell 700. The rear side is coated with an aluminum rear contact 730 and has rear side tabbing layers 740 distributed over the silicon wafer 710. Metallization layers on solar cells are fabricated by first printing the front side silver paste followed by the silver rear tabbing paste and then the aluminum paste. Each paste is dried individually at between 100C and 250C for between 10 and 900 seconds and then co-fired at a peak temperature between 650 and 900C for approximately one second.

In some embodiments silicon solar cells are connected to one another by soldering tin solder coated copper tabbing ribbons to the front busbars and rear tabbing layers. Solder fluxes that are commercially designated as either RMA (e.g., Kester® 186) or R (e.g., Kester® 952) are deposited on the front busbars and rear tabbing layers. A tinned copper ribbon, which is between 1.3 and 3 mm wide and 100-300 um thick is then placed on the solar cell and contacted to the front busbars and the rear tabbing layers with a solder iron at a temperature between 200° C. and 400° C. The solder joints formed during this process have a mean peel strength that is greater than 1 N/mm (e.g., a 2 mm tabbing ribbon would require a peel force of greater than 2N to dislodge the tabbing ribbon).

Silver nanoparticle metallization pastes disclosed herein can be used as drop in replacements for commercial Ag based pastes to form the rear tabbing layer. In one embodiment, a commercially available front side metallization paste is screen printed onto the front side of a solar cell and dried at 100-250° C. to form the fine grid line and busbar layers on the front surface of the wafer. A silver nanoparticle metallization rear tabbing paste, such as any of those described in Table I, is then screen printed onto the back side of a solar cell and dried at 100-250° C. to form the rear tabbing layer 720. A rear aluminum paste is subsequently printed and dried and the entire wafer is co-fired to 650-900° C. for approximately one second in air.

Ag/NIMP pastes used for the rear tabbing layer of a solar cell can have a bulk resistivity that is several times higher than pure Ag pastes but have identical power conversion efficiencies. Table II shows the key photovoltaic properties averaged over 10 solar cells for monocrystalline solar cells made with pure Ag pastes and those made with pure Ag pastes on the front side and Ag/NIMP paste used for the rear tabbing layer. Properties include open-circuit voltage (V_{oc}), short circuit current (I_{sc}), short circuit current density (J_{sc}), fill factor (FF), efficiency (Eff), idealty factor (n-factor), series resistance (RSERIES), and shunt resistance (RSHUNT). The Ag/NIMP paste contained over 25% wt Ag nanoparticles and over 20 wt % NIMP, which were core shell particles with a Ni core and a Ni:B shell. The Ag/NIMP has nearly identical electrical properties and standard deviations for all key PV cell metrics including power conversion efficiency, open-circuit voltage, and short circuit current.

TABLE II
Solar Cell Efficiencies for Solar Cells Made with
Rear Tabbing Pastes of Pure Ag versus Ag/NIMP

| Paste | | | J_{sc} | | | n- | RSERIES | RSHUNT |
|---|---|---|---|---|---|---|---|---|
| Type | V_{oc} (V) | I_{sc} (A) | (mA/cm²) | FF (%) | Eff (%) | factor | (Ω-cm2) | (Ω-cm2) |
| Standard | 0.643 | 9.062 | 37.92 | 79.60 | 19.41 | 1.05 | 0.58 | 8835 |
| Ag paste | | | | | | | | |
| Stdev | 0.0004 | 0.0230 | 0.0963 | 0.2425 | 0.0576 | 0.014 | 0.049 | 6520 |
| Ag/NIMP | 0.643 | 9.048 | 37.86 | 79.76 | 19.42 | 1.06 | 0.54 | 10514 |
| Paste | | | | | | | | |
| Stdev | 0.0005 | 0.0245 | 0.1034 | 0.1991 | 0.0513 | 0.007 | 0.039 | 1837 |

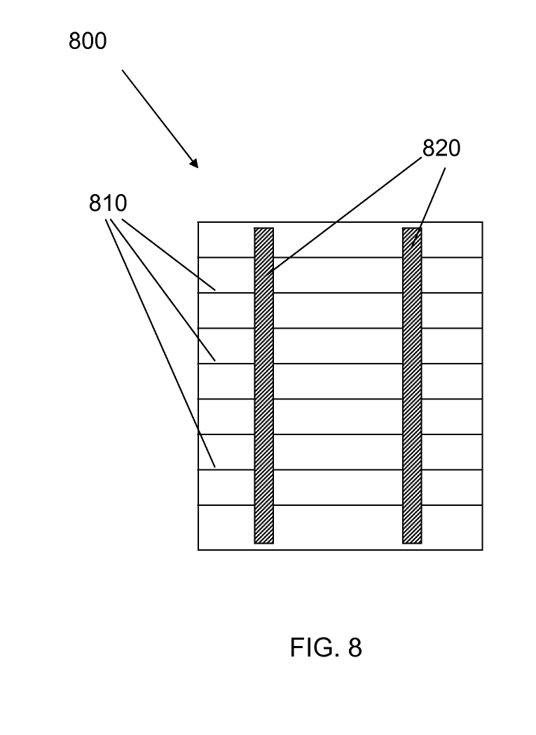

Solar Cell Fabrication Using Silver Nanoparticle Front Busbar Pastes Silver nanoparticle metallization pastes disclosed herein can be used as drop in replacements for commercial Ag based pastes to form the front busbar layer. FIG. 8 is a schematic drawing that shows the front (or illuminated) side of a silicon solar cell, according to an embodiment of the invention. In one embodiment, a commercially available front side metallization paste is screen printed and dried at 100-250° C. to form the fine grid line 810. A silver nanoparticle front busbar paste is then screen printed and dried at 100-250° C. to form the front busbar layers 820. The rear tabbing paste and rear aluminum paste are subsequently printed and dried, as described above, and the entire wafer is co-fired to 650-900° C. for approximately one second in air. In one arrangement, screen printed front busbar coatings range in thickness between about 3 and 15 μm after co-firing. The front busbar layer has a bulk conductivity that is 2 to 10 times less conductive than bulk silver, which has a bulk resistivity of about 1.5E-8 ohms-m. The resulting morphology of the front busbar layer is a condensed particle morphology, which is defined as a sintered and compacted silver matrix that contains dispersed NIMP, elements from the glass frit and/or reaction products from the glass frit and silicon. Sintered and compacted silver films are defined as having tightly packed spherical or distorted spherical silver regions with less porosity than randomly packed hard spheres, and the contact areas between regions of silver are higher than in the case of tightly packed hard spheres. The morphology of some embodiments can also be described as a sintered and compacted silver matrix with dispersed NIMP. The resulting front busbar layer can have a weight ratio of silver to nondeformable inorganic material particles (Ag:NIMP) of 1:9, or 1:1, or 5:1 depending on the desired conductivity and peel strength. The fine grid lines and/or the rear tabbing layer can also have a weight ratio of silver to nondeformable inorganic material particles (Ag:NIMP) of 1:9, or 1:1, or 5:1.

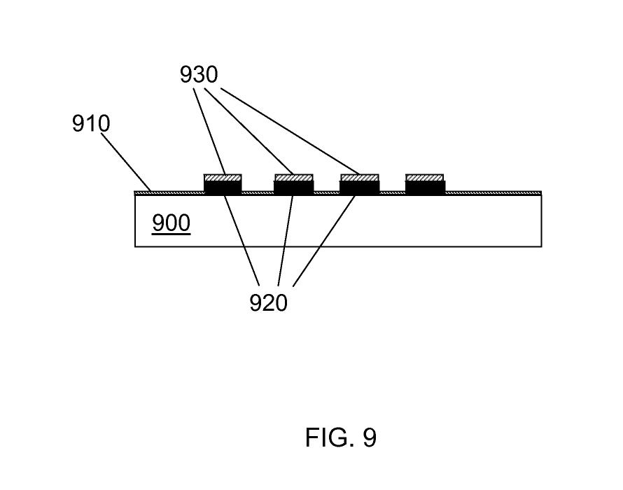

FIG. 9 is a schematic cross-section drawing that shows metallizations on the front side of a solar cell, according to an embodiment of the invention. FIG. 9 shows solar cell 900 that is coated with an anti-reflective coating 910 on its front side. A silver paste is applied to the anti-reflective coating 910 to form fine grid lines 920 that fire through the antireflective coating. Such grid lines may have a thickness between about 10 μm and 50 μm. The fine grid layers 920 are seen in transverse cross section and run into and out of the page. A silver nanoparticle front busbar paste is then screen printed and dried at 100-250° C. to form second fine grid line layers 930 over the fine grid line layers 920 and additionally form front busbar layer (not shown). Thus, two layers make up stacked fine grid layers on the front side of the solar cell 910. The stacked fine grid layers have a Ag film 920 on the surface of the anti-reflective coating and a NIMP/Ag composite film 930 available for contacting a tabbing ribbon. The moderately conductive NIMP/Ag composite layer 930 on the silver fine grid line 920 can further reduce the overall series resistance of the fine grid lines, as current travels in parallel between the layers. In an exemplary embodiment, a stacked fine grid layer that has a 20 μm thick Ag layer with a bulk resistance that is that of pure Ag and a 20 μm thick NIMP/Ag composite layer with a bulk resistance that is 2 times that of pure Ag and has an overall resistance that is 67% lower than the resistance for the single Ag layer alone.

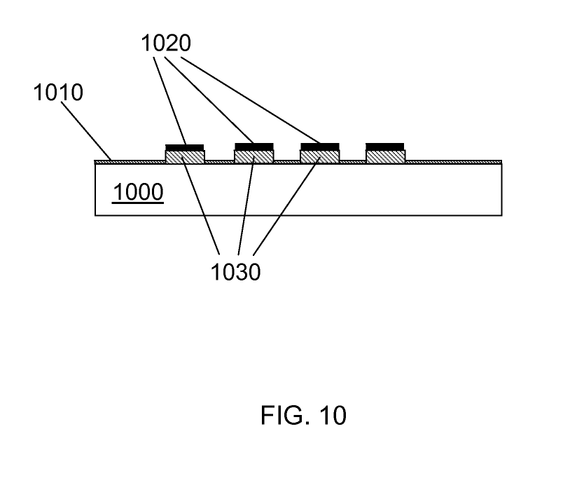

FIG. 10 is a schematic cross-sectional drawing that shows metallization layers and wafer on the front side of a solar cell 1000, according to another embodiment of the invention, in which the order of deposition is reversed. A silver nanoparticle front busbar paste is screen printed onto the solar cell 1000 and then dried at 100-250° C. to form front busbar layers (not shown) and to form a first fine grid line layer 1030 for a stacked fine grid line structure. Subsequently, a silver paste is applied over the fine grid line layer 1030 to form a second layer 1020. Thus, the resulting stacked fine grid line layer has a Ag/NIMP composite film on the surface of the solar cell 1000 and a silver film available for contacting a tabbing ribbon. Again, the moderately conductive Ag/NIMP composite layer 1030 reduces the overall series resistance of the fine grid lines as current travels in parallel between the layers.

### Other PV Cell Architectures

Silver nanoparticle pastes can be used in other, more complex, Si PV architectures, such as emitter wrap through and selective emitter cell architectures. Other examples include architectures where only fine grid lines are printed with no busbars and those that use fine wire network technologies to connect cells in a module. The metallization pastes described above may also be used in metal wrap through as well as passivated emitter rear contact (PERC) solar cells. The silver nanoparticle paste, described herein, can be used as a drop in replacement for Ag based pastes anywhere that Ag pastes are used currently.

Fine grid lines on solar cells are responsible for making good electrical contact to the silicon emitter layer and transporting current from the emitter over a distance of centimeters to the busbar of the solar cell. Two important materials properties affect fine grid line design on solar cells: the bulk resistivity and the contact resistance between the fine grid line and the emitter layer. When the fine grid lines are highly conductive (e.g., within a factor of two of bulk Ag, which is the most conductive element) then the grid lines can be made thinner to reduce shading losses. Frits and other additives can be used in metallization pastes to fire through the anti-reflective coating and make ohmic contact to doped silicon. The additives in the metallization pastes determine the minimum required doping density of the emitter to make good electrical contact. The doping density of the emitter also affects the optimal grid spacing on a silicon solar cell.

For the currently standard two- and three-busbar silicon solar cells, the total series resistance of the solar cell may be dominated by series resistance of individual fine grid lines. As an example, for a two-busbar cell, 15% multi-crystalline PV cell, the series resistance from the fine grid lines represents 73% of the total series resistance (D. L. Meier “Determining components of series resistance from measurements on a finished cell”, IEEE (2006) p 1315). Fine grid layers have been made up of pure Ag particles and have a bulk conductivity that is 1.1 to 2 times less conductive than bulk silver, which has a bulk resistivity of about 1.5E-8 ohms-m. The series resistance of fine grid lines is proportional to the spacing between busbars (a), the bulk resistivity (p_{f}), fine grid line thickness (t), and fine grid line width (w) as shown in equation (1). It should be noted that increasing the number of busbars by a factor of two reduces the fine grid line series resistance by a factor of four.

$${r}_{s} ( fine grid lines ) ∼ \frac{2}{3} {a}^{2} \frac{{p}_{f}}{tw} \\ a = \frac{Cell Width}{2 * busbar ( \# )} \qquad ( 1 )$$

p_{f}=fine grid line bulk resistivity
t=fine grid line thickness
w=fine grid line width

The table below highlights the effect of the number of busbars versus the series resistance of the fine grid lines. For a large number of busbars (e.g., >4) the series resistance drops significantly. When a six inch solar cell has four or more busbars, the spacing between the busbars is less than 4 cm or less than 2 cm.

| Fraction of Total | | | | | |
|---|---|---|---|---|---|
| Resistance for two | Series | Busbar | Cell | | Areal |
| busbar cell | Resistsance | Number | Length | a | Resistance |
| % | Ohm | # | (cm) | (cm) | R/cm\hat{ }2 |
| 73% | 0.7594 | 2 | 15 | 3.75 | 0.054 |
| 33% | 0.3375 | 3 | 15 | 2.50 | 0.054 |
| 18% | 0.1898 | 4 | 15 | 1.88 | 0.054 |
| 12% | 0.1215 | 5 | 15 | 1.50 | 0.054 |
| 8% | 0.0844 | 6 | 15 | 1.25 | 0.054 |
| 6% | 0.0620 | 7 | 15 | 1.07 | 0.054 |
| 5% | 0.0475 | 8 | 15 | 0.94 | 0.054 |
| 4% | 0.0375 | 9 | 15 | 0.83 | 0.054 |
| 3% | 0.0304 | 10 | 15 | 0.75 | 0.054 |
| 2% | 0.0251 | 11 | 15 | 0.68 | 0.054 |
| 2% | 0.0211 | 12 | 15 | 0.63 | 0.054 |
| 2% | 0.0180 | 13 | 15 | 0.58 | 0.054 |
| 1% | 0.0155 | 14 | 15 | 0.54 | 0.054 |
| 1% | 0.0135 | 15 | 15 | 0.50 | 0.054 |
| 1% | 0.0119 | 16 | 15 | 0.47 | 0.054 |
| 1% | 0.0105 | 17 | 15 | 0.44 | 0.054 |
| 1% | 0.0094 | 18 | 15 | 0.42 | 0.054 |
| 1% | 0.0084 | 19 | 15 | 0.39 | 0.054 |
| 1% | 0.0076 | 20 | 15 | 0.38 | 0.054 |

By adding additional busbars to a solar cell, the current per tabbing ribbon can be reduced, thus reducing the overall power loss in the module. By increasing the busbar density on the solar cell, the average distance that current must travel along the fine grid lines can be drastically reduced, which can lower the overall series resistance of the cell. This also allows for using metallization layers for fine grid lines that are less conductive than silver. If fine grid lines with a slightly higher bulk resistivity than silver are used, it may be possible to offset those losses by adding a higher density of busbars.

### Solar Cell Fabrication Using Ag/NIMP Fine Grid Lines

In one embodiment, a silver nanoparticle paste is screen printed and dried at 100-250C to form the fine grid lines and front busbar layers. The rear Ag paste and rear aluminum paste layers are subsequently printed and dried, and the entire wafer is fired to 650-900° C. for approximately one second in air to form ohmic contacts and promote adhesion. The resulting morphology of the fine grid line layer is a condensed particle morphology that comprises a silver phase that can contain elements from the glass frit and a phase resulting from the NIMP. These phases can be measured using x-ray diffraction and the individual elemental compositions can be seen using energy dispersive x-ray spectroscopy. The resulting fine grid line layers can have a weight ratio of silver to NIMP (Ag:NIMP) of 1:9, or 1:1, or 4:1 depending on the desired conductivity and peel strength.

In one arrangement, screen printed coatings range in thickness between about 20 and 50 μm and are dried at 100-250° C. It should be noted that it is possible to make thicker films by using successive printing steps. The resulting fine grid line layers have a conductivity that is 1.5 to 7 times lower than the bulk resistivity of pure silver.

The main components of metallization pastes have been described above. The ratio of silver particles to NIMP can vary from 1:9 by weight (i.e., 10 wt % Ag particles to 90 wt % core-shell NIMP), to 4:1 by weight (i.e., 80 wt % Ag particles versus 20 wt % NIMP) depending on the desired conductivity for various applications. In various embodiments, the fraction of NIMP is between about 80 wt % and 20 wt %, between about 70 wt % 30 wt %, or between about 60 wt % and 40 wt %. In various embodiments, the weight ratio of silver particles to NIMP is between about 1:9 and 4:1, about 1:5 and 4:1, between about 3:7 and 7:3, between about 2:3 and 3:2, or about 1:1. When screen printed, dried at 100-250° C. for approximately three minutes, and rapidly fired in air to 650-900° C., these pastes form a condensed particle network on the substrate, that is, their volumes are reduced by one or more processes during firing, such as, evaporation of carrier, sintering, etc. In some embodiments, film thicknesses are between about 4 and 50 μm with a bulk resistivity that is 1.5 to 10 times higher than that of pure Ag using a four point Van der Pauw measurement on insulating substrates. The bulk resistivity is dependent upon the NIMP:Ag weight ratio and the choice of glass fits. In another arrangement, the films have a bulk resistivity that is 1.5 to 7 times greater than the bulk resistivity of silver, which is 1.5E-8 ohms-m. In another arrangement, the films have a bulk resistivity between about 2 E-8 and 10 E-8 ohms-m.

In another embodiment, the same paste composition is printed for both front side layers simultaneously and would technically be considered a front side paste. There are also many different combinations of NIMP and Ag based pastes that can be deposited onto silicon solar cells. One example, is to use silver nanoparticle pastes to form both front busbar and rear tabbing electrodes while the fine grid lines are made with Ag pastes. Many different architectures can be fabricated using the three types of silver nanoparticle metallization pastes described above.

This invention has been described herein in considerable detail to provide those skilled in the art with information relevant to apply the novel principles and to construct and use such specialized components as are required. However, it is to be understood that the invention can be carried out by different equipment, materials and devices, and that various modifications, both as to the equipment and operating procedures, can be accomplished without departing from the scope of the invention itself.

We claim:

1. A electrode metallization paste comprising:
a plurality of silver particles comprising between 10 wt % and 50 wt % of the paste wherein;
more than 50 wt % of the silver particles are nanoparticles that have a D50 diameter between 10 nm and 1000 nm, the nanoparticles configured to deform upon firing at temperatures greater than 500° C.; and
less than 50 wt % of the silver particles are microparticles with at least one dimension greater than 1000 nm;
a plurality of nondeformable inorganic material particles comprising more than 10 wt % of the paste; and
glass frit;
wherein the silver particles, the nondeformable inorganic material particles, and the glass frit are all mixed together in an organic vehicle.

2. The metallization paste of claim 1 wherein the paste has a viscosity between 10,000 and 200,000 cP at 25° C. and at a sheer rate of 4 sec⁻¹.

3. The metallization paste of claim 1 wherein the paste has a solids loading between 30 wt % and 70 wt %.

4. The metallization paste of claim 1 wherein the silver particles and the nondeformable inorganic material particles together make up between 30 wt % and 70 wt % of the paste.

5. The metallization paste of claim 1 wherein the silver particles and the nondeformable inorganic material particles together make up between 75 wt % and 90 wt % of the paste.

6. The metallization paste of claim 1 wherein the nondeformable inorganic material particles comprise a metal selected from the group consisting of nickel (Ni), cobalt (Co), aluminum (Al), boron (B), phosphorus (P), and alloys thereof.

7. The metallization paste of claim 1 wherein the nondeformable inorganic material particles comprise a material selected from the group consisting of aluminum (Al), tin (Sn), zinc (Zn), lead (Pb), antimony (Sb), nickel (Ni), boron (B), phosphorus (P), magnesium (Mg), molybdenum (Mo), manganese (Mn), tungsten (W), and alloys, composites, and other combinations thereof.

8. The metallization paste of claim 1 wherein the nondeformable inorganic material particles comprise an oxide that includes at least one element selected from the group consisting of silicon (Si), boron (B), nickel (Ni), cobalt (Co), aluminum (Al), molybdenum (Mo), manganese (Mn), tungsten (W), chromium (Cr), tin (Sn), zinc (Zn), lead (Pb), and antimony (Sb).

9. The metallization paste of claim 1 wherein the nondeformable inorganic material particles comprise core-shell particles that have an outer shell made of a nondeformable inorganic material.

10. The metallization paste of claim 1 wherein the silver nanoparticles have a D50 that is between 10 nm and 500 nm.

11. The metallization paste of claim 1 wherein the nondeformable inorganic material particles have a D50 range between 200 nm and 1000 nm.

12. The metallization paste of claim 1, wherein the metallization paste comprises 40 wt % silver nanoparticles, 11 wt % silver microparticles, 21 wt % nondeformable inorganic material particles, 3 wt % glass frit, and 25 wt % organic vehicle.

13. The metallization paste of claim 1, wherein the metallization paste comprises 12 wt % silver nanoparticles, 3 wt % silver microparticles, 35 wt % nondeformable inorganic material particles, 4 wt % glass frit, and 46 wt % organic vehicle.

14. A solar cell comprising:
a silicon substrate having a front surface and a back surface;
a plurality of fine grid lines on the front surface of the silicon substrate;
at least one front busbar layer on the front surface of the silicon substrate, the front busbar layer in electrical contact with the plurality of fine grid lines;
an aluminum layer on the back surface of the silicon substrate; and
at least one rear tabbing layer on the back surface of the silicon substrate;
wherein at least one of the plurality of fine grid lines, the front busbar layer, or the rear tabbing layer comprises:
a condensed particle morphology that consists of nondeformable inorganic material particles dispersed in a silver matrix, such that the weight ratio of silver to nondeformable inorganic material particles is 5:1
wherein the nondeformable inorganic material particles comprise aluminum (Al), tin (Sn), zinc (Zn), lead (Pb), antimony (Sb), nickel (Ni), cobalt (Co) boron (B), phosphorus (P), magnesium (Mg), molybdenum (Mo), manganese (Mn), tungsten (W), and alloys, composites, or other combinations thereof.

15. The solar cell of claim 14, wherein the rear tabbing layer comprises a condensed particle morphology that consists of nondeformable inorganic material particles dispersed in a silver matrix and wherein the rear tabbing layer has a peel strength of more than 1 N/mm when soldered to tin coated copper tabbing ribbons using tin based solders and fluxes

16. The solar cell of claim 15, wherein the rear tabbing layer has a conductivity that is 2 to 10 times less than the conductivity of bulk silver.

17. The solar cell of claim 14, wherein the front busbar layer comprises a condensed particle morphology that consists of nondeformable inorganic material particles dispersed in a silver matrix and wherein the front busbar layer has a peel strength of more than 1 N/mm when soldered to tin coated copper tabbing ribbons using tin based solders and fluxes.

18. The solar cell of claim 17, wherein the front busbar layer has a conductivity that is 2 to 10 times less than the conductivity of bulk silver.

19. The solar cell of claim 17, wherein the front surface of the silicon substrate has an anti-reflective coating, and the front busbar layers do not penetrate through the anti-reflective coating and do not make electrical contact to the silicon substrate.

20. The solar cell of claim 17, wherein the front surface of the silicon substrate has a silicon emitter layer, and the front busbar layer makes electrical contact to the silicon emitter layer.

21. The solar cell of claim 14, wherein the fine grid lines comprise a condensed particle morphology that consists of nondeformable inorganic material particles dispersed in a silver matrix and wherein the fine grid lines have a conductivity that is 1.5 to 7 times less than the conductivity of bulk silver.

22. The solar cell of claim 21, wherein the front surface of the silicon substrate has a silicon emitter layer, and the fine grid lines make electrical contact to the silicon emitter layer with a contact resistance less than 100 mohm-cm².

23. The solar cell of claim 21, wherein there is an additional metal layer between the fine grid lines and the silicon substrate and wherein the additional metal layer consists of silver.

24. The solar cell of claim 21, wherein there is an additional metal layer over the fine grid lines and wherein the additional metal layer consists of silver.
